(19) United States
(12) Patent Application Publication
(10) Pub. No.: US 2008/0099796 A1
(43) Pub. Date: May 1, 2008

(54) Device with patterned semiconductor electrode structure and method of manufacture

(76) Inventor: Madhukar B. Vora, Los Gatos, CA (US)

Correspondence Address: Bradley T. Sako;HAVERSTOCK & OWENS, LLP, 162 North Wolfe Road, Sunnyvale, CA, 94086, US

(21) Appl. No.: 11/591,916

(22) Filed: Nov. 1, 2006

(51) Int. Cl. H01L 29/80; H01L 21/337

(52) U.S. Cl. 257/256; 257/506; 438/186; 438/689

(57) ABSTRACT

A method of forming a semiconductor device can include forming a first layer of semiconductor material in contact with a first area of a substrate. The first area can be adjacent to at least one electrical isolation structure that extends into the substrate and has a top portion extending above a surface of the substrate. The method can also include etching, with a degree of anisotropy, the first layer to form at least a first structure in contact with the first area. Further, in a step separate from the etching step, retention of residual semiconductor material at a junction of the substrate and the at least one electrical isolation structure can be prevented.

### TECHNICAL FIELD

The present invention relates generally to semiconductor circuits, and more particularly to semiconductor circuits having electrode structures of active devices formed over a substrate.

### BACKGROUND OF THE INVENTION

Commonly owned, co-pending U.S. patent application Ser. No. 11/261,873 filed on Oct. 28, 2005, titled “INTEGRATED CIRCUIT USING COMPLEMENTARY JUNCTION FIELD EFFECT TRANSISTOR AND MOS TRANSISTOR IN SILICON AND SILICON ALLOYS”, and Ser. No. 11/452,442 filed on Jun. 13, 1006, titled “CIRCUIT CONFIGURATIONS HAVING FOUR TERMINAL JFET DEVICES”, both by Ashok K. Kapoor, disclose, amongst other matters, a junction field effect transistor (JFET) formed by patterning a layer of polysilicon, or some other semiconductor material, deposited on a semiconductor substrate. The contents of this application are incorporated by reference herein.

When such devices are fabricated in conjunction with some isolation structures, there is a potential for the formation of defects. One particular example of such a possible defect source is shown in a series of cross sectional views in FIGS. 15A to 15C.

FIG. 15A shows a semiconductor device 1500 that includes a semiconductor substrate 1502 having isolation structures 1504-0 and 1504-1 formed therein. Isolation structures (1504-0 and 1504-1) can have portions that extend above a substrate surface. Isolation structures (1504-0 and 1504-1) can be conventional shallow trench isolation (STI) structures that provide electrical isolation between active devices, such as transistors. In FIG. 15A, a layer of polycrystalline silicon (polysilicon) 1506 has been conformally deposited over both a top surface of the substrate 1502 and isolation structures (1504-0 and 1504-1). As a result, polysilicon occupies a corner, or junction (one shown as 1505) formed at an intersection of an isolation structure and the substrate top surface.

FIG. 15B shows the semiconductor device 1500 following the formation of an insulating layer 1508 over the polysilicon layer 1506. In addition, an etch mask 1510 has been formed on the insulating layer 1508. Etch mask 1510 can be used to transfer a mask pattern to layers 1506/1508 by way of an etch step that forms an electrode of an active device (e.g., gate electrode, drain electrode, source electrode).

FIG. 15C shows the semiconductor device 1500 following an electrode formation step. Polysilicon layer 1506 and insulating layer 1508 can be etched with an anisotropic etch to form an electrode structure 1512.

Preferably, an etch step such as that represented by FIG. 15C should form an electrode to a desired size and profile, while at the same time not damage a substrate surface. However, as shown in FIG. 15C, for some etch processes and/or equipment, an etch removal step may result in residual polysilicon (e.g., 1514) remaining at a junction formed by the surface of semiconductor substrate 1502 and top portions of isolation structures (1504-0 and 1504-1).

FIG. 16 shows a top down view of a semiconductor device 1600 that contains residual polysilicon 1614 at a substrate-isolation structure 1604 interface. FIG. 16 shows three electrode structures 1612-0, 1612-1 and 1612-2. Residual polysilicon 1614 can provide unwanted current paths between electrodes (1612-0, 1612-1 and 1612-2), thus adversely affecting a manufactured device.

### BRIEF DESCRIPTION OF THE DRAWINGS

FIG. 1 is a flow diagram showing a method according to a first embodiment.

FIG. 2 is a flow diagram showing a method according to a second embodiment.

FIGS. 3A to 3F are side cross sectional views showing one example of the method of FIG. 2.

FIG. 4 is a flow diagram showing a method according to a third embodiment.

FIGS. 5A to 5E are side cross sectional views showing one example of the method of FIG. 4.

FIGS. 6A to 6I are side cross sectional views showing a method of manufacturing complementary junction field effect transistors (JFETs) according to a fourth embodiment.

FIGS. 7A to 7G are side cross sectional views showing a method of manufacturing complementary JFETs according to a fifth embodiment.

FIGS. 8A to 8I are side cross sectional views showing a method of manufacturing JFETs with insulated gate FETs (IGFETs) according to a sixth embodiment.

FIGS. 9A to 9G are side cross sectional views showing a method of manufacturing JFETs with IGFETs according to a seventh embodiment.

FIGS. 10A to 10H are side cross sectional views showing a method of manufacturing JFETs with bipolar junction transistors (BJTs) according to an eighth embodiment.

FIGS. 11A to 11G are side cross sectional views showing a method of manufacturing JFETs with BJTs according to a ninth embodiment.

FIGS. 12A and 12B are side cross sectional views showing examples of JFETs manufactured according to disclosed embodiments.

FIGS. 13A and 13B are side cross sectional views showing examples of IGFETs manufactured according to disclosed embodiments.

FIGS. 14A and 14B are side cross sectional views showing examples of BJTs manufactured according to disclosed embodiments.

FIGS. 15A to 15C are side cross sectional views showing a process that can produce unwanted residual polycrystalline silicon.

FIG. 16 is a top plan view a structure resulting from a method like that shown in FIGS. 15A to 15C.

### DETAILED DESCRIPTION OF THE EMBODIMENTS

Various embodiments of the present invention will now be described in detail with reference to a number of drawings. The embodiments show electrode structures and methods for forming such structures that can have essentially no residual electrode material formed at a junction of a substrate surface and an isolation structure. It is understood that the various figures are not drawn to scale and can vary according to manufacturing process and desired device performance.

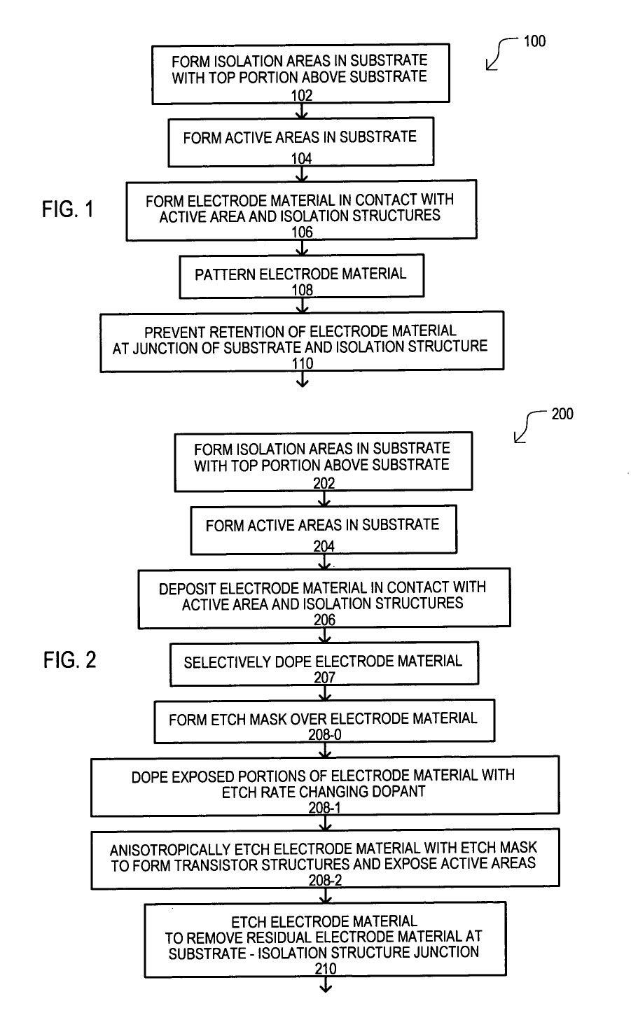

Referring now to FIG. 1, a method according to a first embodiment is shown in a flow diagram and designated by the general reference character 100. A method 100 can include forming isolation areas in a substrate with top portions that extend above a substrate (step 102). As but one example, such a step can include forming shallow trench isolation (STI) structures according to conventional techniques.

A method 100 can also include forming active areas in a substrate (step 104). Such a step can include forming differently doped regions within substrate, by way of ion implantation as but one example. Even more particularly, in one variation such a step can include forming one or more wells within a semiconductor substrate doped to an opposite conductivity type as the substrate. In addition, additional doping steps can be performed to adjust different portions of the substrate (e.g., surface) to a desired conductivity (i.e., channel or threshold voltage implants).

An electrode material can then be formed in contact with the active area and isolation structures (step 106). An electrode material can include, amongst other layers, a semiconductor material. Such a step can result in the semiconductor material being formed at a junction of a substrate surface and top portions of the isolation areas.

Once formed, an electrode material can be patterned (step 108). Such a step can form electrode structures in contact with an active area. As but one example, a step 108 can selectively remove the electrode material to expose portions of the active area. Resulting electrode structures can include, without limitation, junction field effect transistor (JFET) gate electrodes, source electrodes, drain electrodes, or well bias electrodes.

It is understood that absent any additional steps, a patterning step (step 108) can result in residual gate material remaining at a junction of a substrate surface and top portions of the isolation areas.

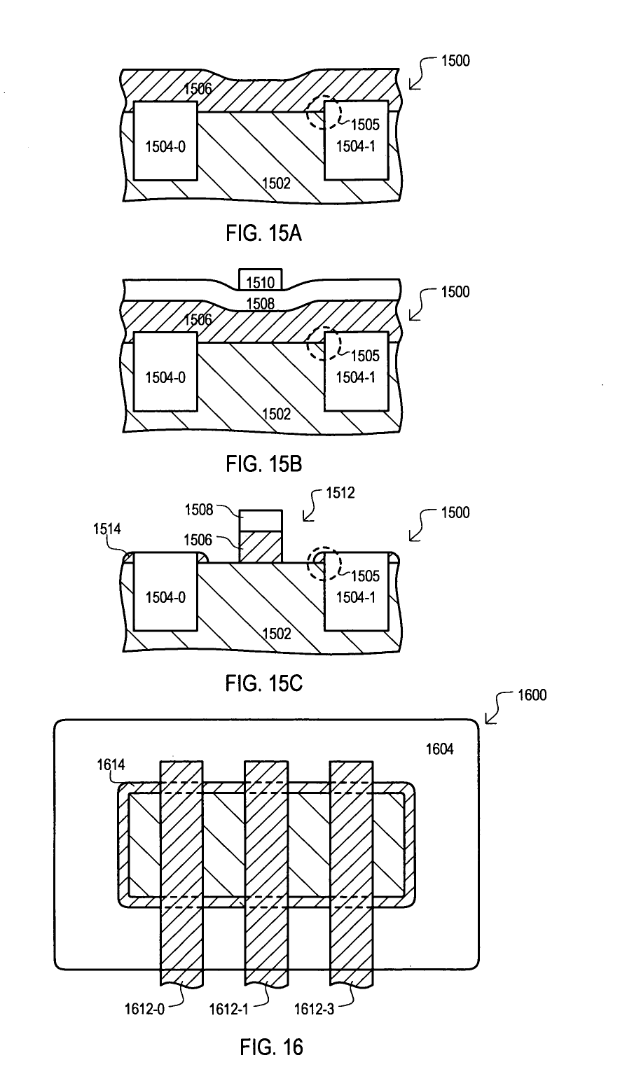

Unlike approaches like that shown in FIGS. 15A to 15C, a method 100 can prevent the retention of gate material at a junction of the substrate and isolation areas (step 110). A step 110 can include removing residual electrode material remaining after a patterning step, or preventing the electrode material from occupying junctions of the substrate and isolation areas by filling such regions with an insulating material prior to depositing the electrode material.

In this way, a semiconductor device can include an electrode, such as a JFET gate, formed in contact with a substrate that does not have residual electrode material at a junction of the substrate and isolation areas adjacent to the electrode structure.

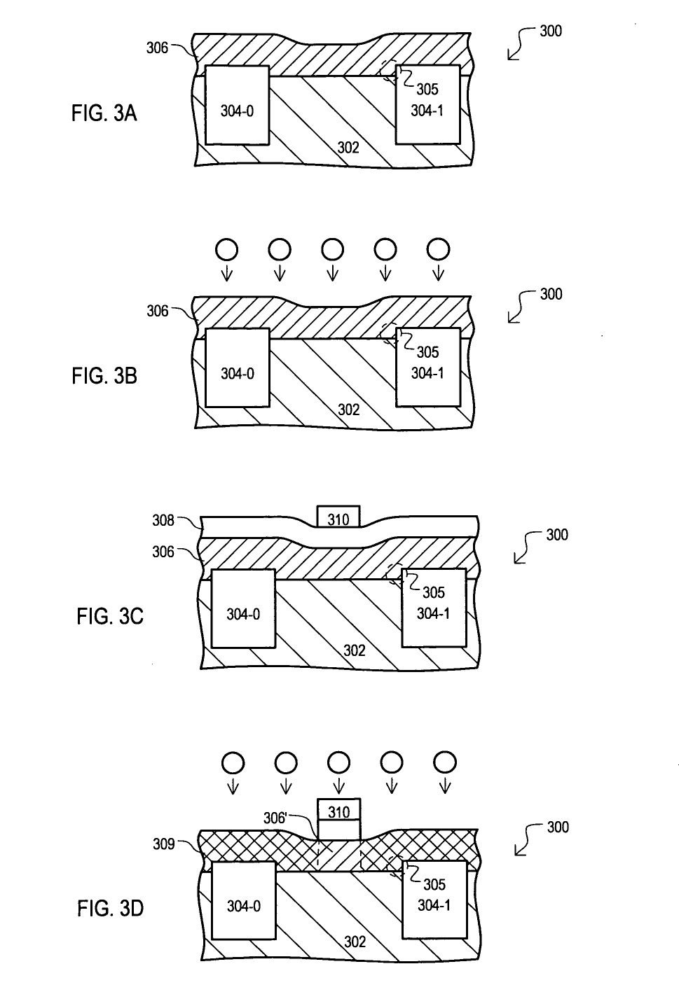

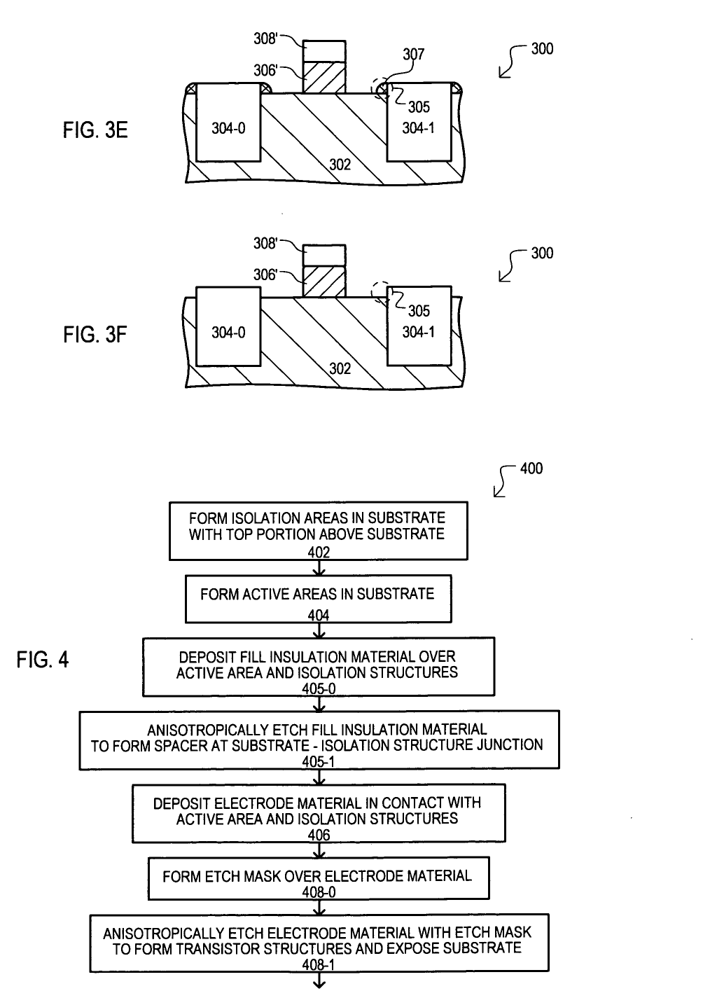

Referring now to FIG. 2, a more detailed embodiment of the present invention will now be described with reference to a flow diagram and a series of side cross sectional views shown in FIGS. 3A to 3E.

Referring to FIG. 2, a method is shown in a flow diagram and designated by the general reference character 200. A method 200 can include some of the same general steps shown in FIG. 1, thus like steps are referred to by the same reference character but with the first digit being a “2” instead of a “1”.

Accordingly, a method 200 can include forming isolation areas (step 202), forming active areas (step 204), and depositing an electrode material (step 206). A device following such steps is shown in FIG. 3A.

FIG. 3A is a side cross sectional view of a semiconductor device 300, showing isolation structures (304-0 and 304-1) formed in a substrate 302 according to a step 202. Isolation structures (304-0 and 304-1) can extend above a top surface of substrate 302. An electrode material 306 can be formed over substrate 302 in contact with both isolation structures (304-0 and 304-1) and a top surface of a substrate 302. As shown in the figure, electrode material 306 can be formed at a junction of a substrate and a top portion (emphasized by label 305).

An electrode material 306 can include a semiconductor material, preferably polycrystalline silicon (polysilicon). However, alternate materials can be used as an electrode material, including but not limited to germanium, silicon carbide, or a silicon/germanium/carbon alloy.

A method 200 of FIG. 2 can also include selectively doping the electrode material (step 207). Such a step is represented by FIG. 3B. A step 207 can include doping different sections of an electrode material to different conductivity types (i.e., n-type or p-type). In one very particular example, a step 207 can be used to dope gate electrode regions (i.e., regions subsequently patterned into gate electrodes) to a conductivity type opposite to a channel region below the gate electrode. Further, a step 207 can be used to dope source/drain/well bias electrode regions to a conductivity type the same as (although not necessarily the same concentration) a contacted active area.

A method 200 can also include forming an etch mask over an electrode material (step 208-0). An example of a semiconductor device 300 following a step 208-0 is shown in FIG. 3C. In the example of FIGS. 2 and 3C, a step 208-0 can include forming an insulating material 308 over an electrode material 306. An insulating material 308 can be formed from silicon dioxide, silicon nitride, silicon oxynitride, or some combination thereof, as but a few examples. An etch mask 310 can then be formed on insulating material 308. An etch mask 310 can be formed according to conventional optical lithographic techniques, including but not limited to the deposition and development of a positive photoresist or negative photoresist, or alternate lithographic techniques including but not limited to immersion lithography, imprint lithography, direct write e-beam lithography, x-ray lithography, or ultraviolet lithography.

An insulating layer 310 can then be patterned according to the etch mask. In a first approach, a first reactive plasma etch can be performed that is highly selective to insulating material 308 over etch mask 310. In a second approach, a first reactive plasma etch can be performed that is highly selective to insulating material 308 over etch mask 310. Etch mask 310 can then be removed allowing a patterned insulating material can be used as a “hard” etch mask.

Method 200 includes doping exposed portions of the electrode material with an etch rate altering dopant (step 208-1). Such a step can including doping those portions of an electrode material that will not function as electrodes in order to alter a relative etch rate between the electrodes and non-electrode regions. An example of a semiconductor device 300 following a step 208-1 is shown in FIG. 3D. In the example shown, an electrode material can be doped to form two different portions, an electrode portion 306′ and a removal portion 309. In one very particular example, an electrode material can be polysilicon, and a doping step can include ion implanting a neutral dopant species. Even more particularly, such a step can include ion implanting argon, silicon, and/or helium at doses of about 1×10¹⁵ to about 1×10¹⁶ ions/cm². An energy for such implantation steps should be suitable to penetrate the electrode material but leave a substrate essentially free of such species. As understood by those skilled in the art, the energy would depend upon the thickness and material of the electrode layer.

A method 200 can continue by anisotropically etching the electrode material with the etch mask to form transistor electrode structures and expose active areas (step 208-2). Such a step can include etching through portions of the electrode material 306 exposed by etch mask 310 to a surface of substrate 302. An anisotropic etch can have a greater etch rate in a direction perpendicular to a substrate surface as opposed to a direction parallel to the substrate, preferably a substantially greater etch in such a direction.

In one very particular example, a step 208-2 can include a reactive plasma etching. More particularly, a reactive plasma etch can be used that is selective to an electrode material 306 over etch mask 310.

As shown in FIG. 3E, following a step 208-2, residual electrode material (one example shown as 307) can remain at a junction of a substrate 302 and a top portion of isolation structures (3040 and 304-1).

Referring still to FIG. 2, a method 200 can include etching the electrode material to remove residual electrode material at a junction of a substrate and top portions of isolation structures (step 210). In one arrangement, a step 210 can include a wet chemical etch selective to a removal portion (e.g., 309) of a gate electrode material over an electrode portion (e.g., 308′) of the gate electrode material. In one very particular arrangement, an electrode material can include polysilicon, and a wet chemical etch can include hydrofluoric acid (HF), nitric acid (HNO₃), or some combination thereof. Even more particularly, such a wet chemical etch can include etching with “HNA”, a combination of HF and HNO₃ buffered with acetic acid. Etch times for such wet chemical etches will vary according to etch recipe used, and amount of residual electrode material to be removed (i.e., resulting step height of isolation structures, etc.), and determinable by those skilled in the art.

While wet chemical etching can be used to perform an etch of residual electrode material, the present invention should not be construed as being limited to wet etching. Alternate etching methods, such as a plasma etch can be used in a step 210. As but one very particular example, in the event an electrode material comprises polysilicon, a plasma etch comprising disassociated chlorine can be utilized. Even more particularly, such a plasma etching can include using chlorine gas (CL₂) as a reactive component.

An etch performed in a step 210 can be isotropic or anisotropic according to the selectivity of the etch. That is, it is preferable that residual gate material 307 be removed with little or any undercutting of a resulting electrode structure (e.g., 308′).

A semiconductor device 300 following a step 210 is shown in FIG. 3F. As shown, a step 210 can remove all or essentially all residual electrode material at a junction 305 of a substrate and a top portion of an isolation structure.

In this way, a method can remove residual portions of an electrode layer formed in contact with a substrate with an etch step separate from an electrode patterning step.

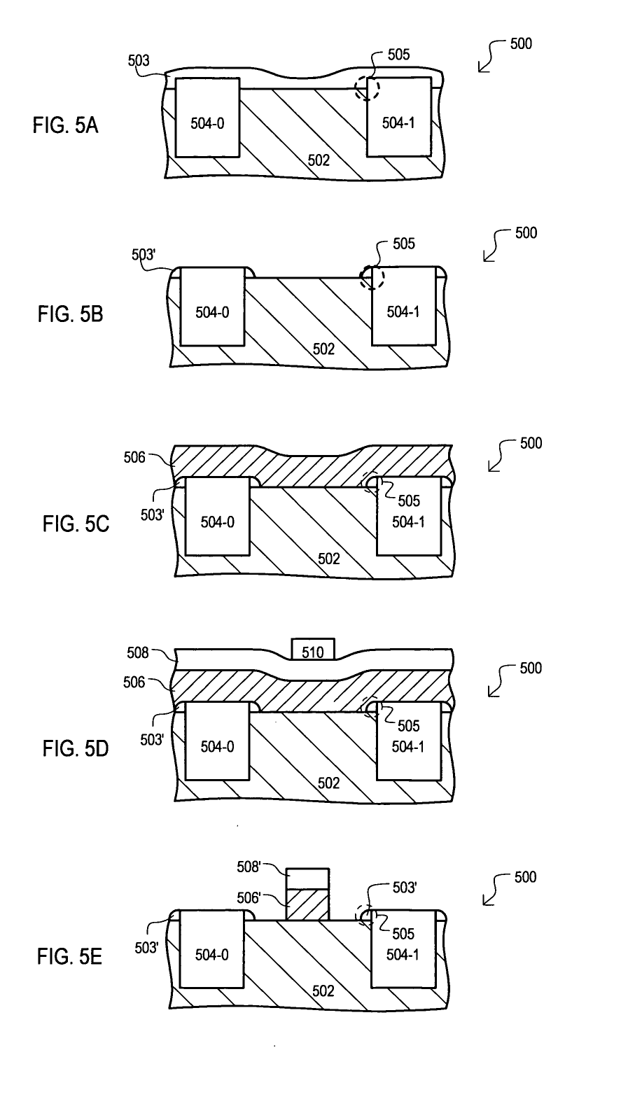

While FIGS. 2 and 3A to 3F show a method in which residual electrode material can be removed following a gate patterning, alternate embodiments can prevent electrode material from being formed at such junctions in the first place. An example of such an arrangement is shown in FIGS. 4 and 5A to 5E.

Referring to FIG. 4, a method is shown in a flow diagram and designated by the general reference character 400. A method 400 can include some of the same general steps shown in FIGS. 1 and 2, thus like steps are referred to by the same reference character but with the first digit being a “3” instead of a “1” or a “2”. Further, FIGS. 5A to 5E can include some of the same general structures as FIGS. 3A to 3E, thus like structures are referred to by the same reference character but with the first digit being a “5” instead of a “3”.

Accordingly, a method 400 can include forming isolation areas (step 402) and forming active areas (step 404).

The embodiment of FIG. 4 can differ from that of FIGS. 1 and 3, in that it can include, prior to depositing an electrode material, depositing a fill insulating material over active areas and isolation structures (step 405-0). Such a step can result in a fill insulating material filling a junction (e.g., corner) formed by a substrate and top portions of isolation structures.

An example of a semiconductor device 500 following a step 405-0 is shown in FIG. 5A. As shown, a fill insulating material 503 can be formed on a substrate 502 and isolation structures (504-0 and 504-1), filling a junction 505 formed by a top surface of substrate 502 and isolation structures (504-0 and 504-1). A fill insulating material is preferably formed of a material that may be etched selectively over a substrate material. As but one very particular example, if a substrate is essentially monocrystalline silicon, a fill insulating material can comprise a silicon oxide, silicon oxynitride, or preferably a silicon nitride.

Referring still to FIG. 4, a method 400 can include anisotropically etching a fill insulating material to form a spacer at a substrate isolation structure junction (405-1). A step 405-1 can remove fill insulation material from a majority of a substrate surface while retaining such a material at a substrate-isolation structure junction 505. Residual fill insulation material can take the form of a fill “spacer” that covers a majority if not all of a vertical face of isolation structure top portion. Further, such a fill spacer can have a tapered shape in cross section, being widest at a substrate surface, and narrowing at locations further away from a substrate surface.

An example of semiconductor device 500 following a step 405-1 is shown in FIG. 5B. Fill insulating material spacers (one shown as 503′) can be formed at substrate—isolation structure junctions (e.g., 505).

A method 400 can continue with steps similar to those of FIG. 3, including depositing an electrode material in contact with an active area and isolation structures (step 406), and forming an etch mask over an electrode material (step 408-0). Semiconductor device 500 following a step 406 is shown in FIG. 5C, and the semiconductor device 500 following a step 408-0 is shown in FIG. 5D.

As shown in FIGS. 5C and 5D, due to the presence of fill spacers (e.g., 503′), an electrode material is not formed at junctions between substrate 502 and isolation structures (504-0 and 504-1).

Unlike the approach of FIG. 2, a method 400 may not include doping exposed portions of an electrode material to alter an etch rate.

However, like FIG. 1, a method 400 can also include anisotropically etching the electrode material with the etch mask to form transistor electrode structures and expose active areas (step 408-1). Such a step can include the same approaches and variations described in conjunction with step 208-1 of FIG. 2.

A semiconductor device 500 following a step 408-1 is shown in FIG. 5E. Unlike the embodiment of FIG. 2, due to the presence of fill spacers (e.g., 503′), after an etch step 408-1, there can be essentially no residual electrode material at junctions 505.

In this way, a method can prevent the formation of residual electrode material at a junction area by creating insulating filling structures at such junctions prior to the formation of an electrode layer.

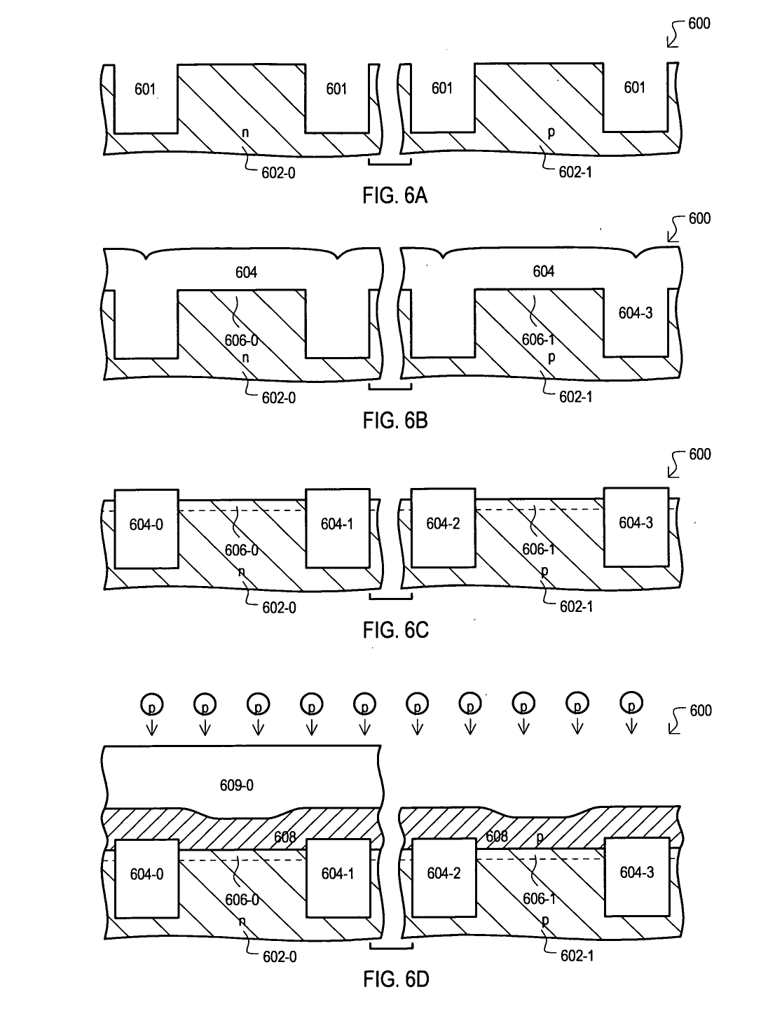

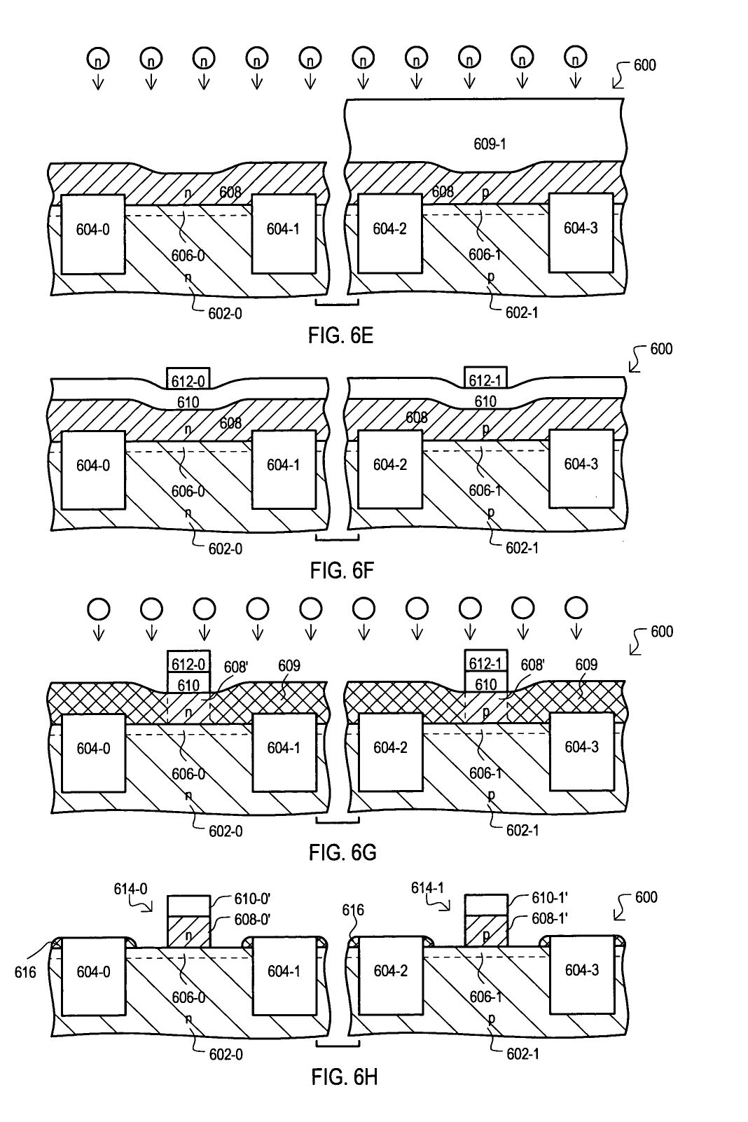

The above embodiments have shown methods that can form JFET structures, including JFET gate, source, drain or well bias electrodes. While such approaches can be used to form multiple JFETs in an integrated circuit, such approaches can also be used to form complementary JFETs in same integrated circuit. One example of such an arrangement is shown in FIGS. 6A to 6I, which show side cross sectional views of a semiconductor device 600 during and following various processing steps.

Referring now to FIG. 6A, a method can include forming trenches 601 in a first portion 602-0 and a second portion 602-1 of a same substrate. Trenches 601 can be formed by masking substrate portions (602-0 and 602-1) with an etch mask that exposes trench regions. An anisotropic etch, such as a reactive ion etch, can then be performed to form trenches to a desired depth. Substrate portions (602-0 and 602-1) can be doped to different conductivity types. In the particular example of FIG. 6A, a first substrate portion 602-0 can be an n-well formed in a p-type substrate by ion implantation, while a second substrate portion 602-1 can be a p-type substrate.

Optionally, after being formed, trenches 602 can be subject to a “liner” step that forms an initial insulating liner layer on the surfaces of the trenches 602. As but two of the many possible examples, such a liner can be deposited silicon nitride or a silicon oxide layer formed by oxidizing exposed trench surfaces.

Referring to FIG. 6B, a trench isolation layer 604 can be deposited over a substrate portions (602-0 and 602-1) to fill trenches 602. A trench isolation layer 604 can be a silicon oxide, preferably a low pressure chemical vapor deposited (LPCVD) silicon oxide.

Referring now to FIG. 6C, a semiconductor device 600 can be subject to a planarization step that removes substantially all portions of trench isolation layer down to about the level of a surface of substrate portions (602-0 and 602-1). Such a step may preferably include a chemical mechanical polishing (CMP) operation. However, alternate methods can include a reactive ion etch back step, or some combination of an etch back and CMP. Planarizing a trench isolation layer over trench locations can form isolation structures 604-0 to 604-3 that can have portions extending above a substrate surface.

FIG. 6C also shows the formation of a channel region of an opposite conductivity type as a substrate. Thus, first substrate portion 602-0 can include a p-type channel 606-0, while second substrate portion 602-1 can include an n-type channel 606-1. Such channel regions (606-0 and 606-1) can be preferably formed with separate ion implantation steps.

An area between isolation regions 604-0 and 604-1 can be considered an active area, as such an area can contain an active device like a JFET. Similarly, an area between isolation regions 604-2 and 604-3 can be considered an active area, as such an area can contain an active device like a JFET.

Referring now to FIGS. 6D and 6E, a method can further include forming an electrode layer 608 over and in contact with active areas in both first and second substrate areas (602-0 and 602-1). An electrode layer 608 is preferably polysilicon. Once deposited, at least a portion of the electrode layer 608 over a second substrate 602-1 can be doped to an opposite conductivity type of a below channel region. Thus, FIG. 6D shows an electrode layer 608 over a second substrate area 602-1 being doped with p-type dopants. At the same time, a first substrate area 602-0 can be masked from such p-type dopants by an implantation mask 609-0. FIG. 6E shows an electrode layer 608 over a first substrate area 602-0 being doped with n-type dopants. At the same time, a second substrate area 602-1 can be masked from such n-type dopants.

In this way, complementary JFET gate conductivities can be created to fabricate different conductivity JFETs in the same substrate.

Referring now to FIG. 6F, a method can include forming an insulating layer 610 over electrode layer 608. Preferably, an insulating layer can be a layer of deposited silicon oxide, silicon oxynitride, or preferably silicon nitride. An etch mask can then be formed on the insulating layer. In the example shown, an etch mask can include a first gate mask 612-0 that can define a gate of a first conductivity type (in this case n-type), and a second gate mask 612-1 that can define a gate of a second conductivity type (in this case p-type).

Referring to FIG. 6G, according to a pattern established by an etch mask, exposed portions of an electrode layer 608 can be doped with an etch rate altering dopant to create electrode portions 608′ and removal portions 609. Such a step can include steps described above, particularly with reference to the method of FIG. 2.

A method can further include anisotropically etching to form gate structures 614-0 and 614-1. Such a step can include etching through electrode layer 608 according to the various approaches described in conjunction with the above embodiments.

Semiconductor device 600 following the above etch step is show in FIG. 6H. Gate structures 6140 and 614-1 can be formed. Gate structure 614-0 can include a top insulating portion 610-0′ and bottom n-type semiconductor portion 608-0′, and thus form a p-channel JFET gate. Similarly, gate structure 614-1 can include a top insulating portion 610-1′ and bottom p-type semiconductor portion 608-1′, and thus form an n-channel JFET gate.

The gate formation etch step can result in residual electrode material (one shown as 616) remaining at corners formed by isolation structures (6040 to 6043) and a surface of substrate portions (602-0 to 602-1). Such residual electrode material can provide undesirable conductive paths in a resulting integrated circuit.

A method can remove residual electrode material with an etch selective to a removal portion 609 over an electrode portion 608′. Such an etch can be isotropic or anisotropic according to impact on the etch profile of electrode structures. As noted in the embodiment of FIGS. 2 and 3A to 3E, this etch step can be a wet chemical etch.

Semiconductor device 600 following a residual electrode material etch is shown in FIG. 6H. As shown in FIG. 6H, a resulting structure can include complementary JFET gate structures (614-0 and 614-1).

In this way, complementary type JFETs can be formed in the same substrate essentially without residual electrode material at isolation corners, by an etch step performed after, and separate from, an electrode formation step.

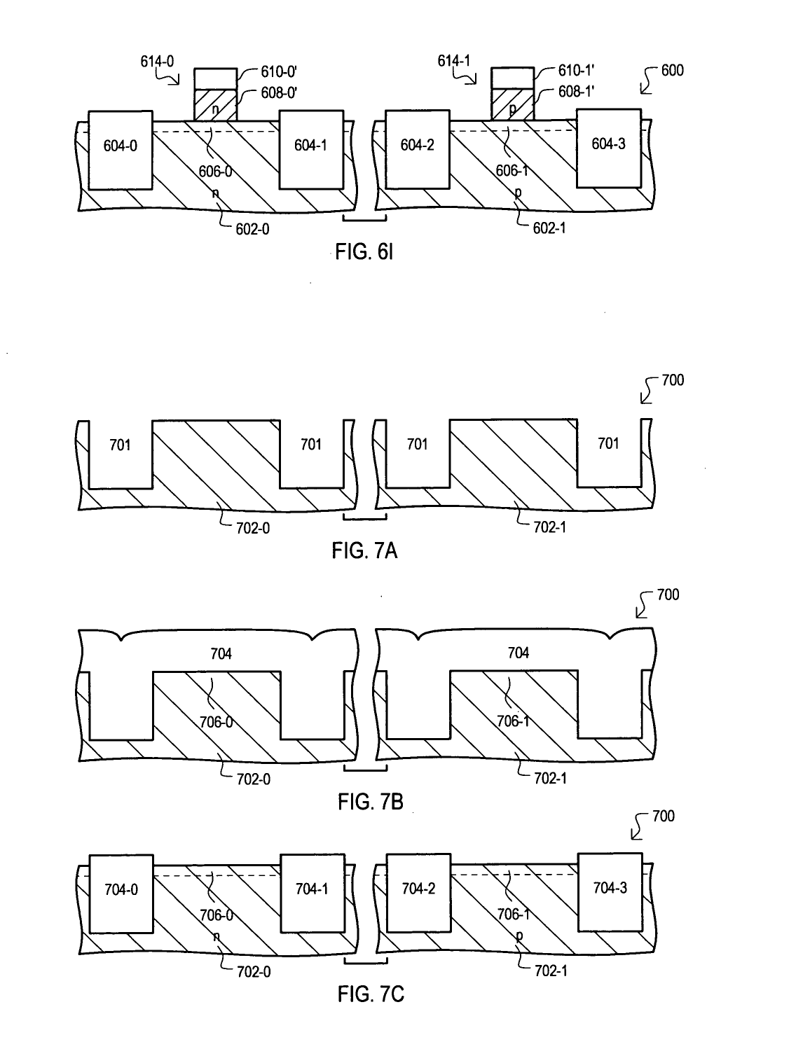

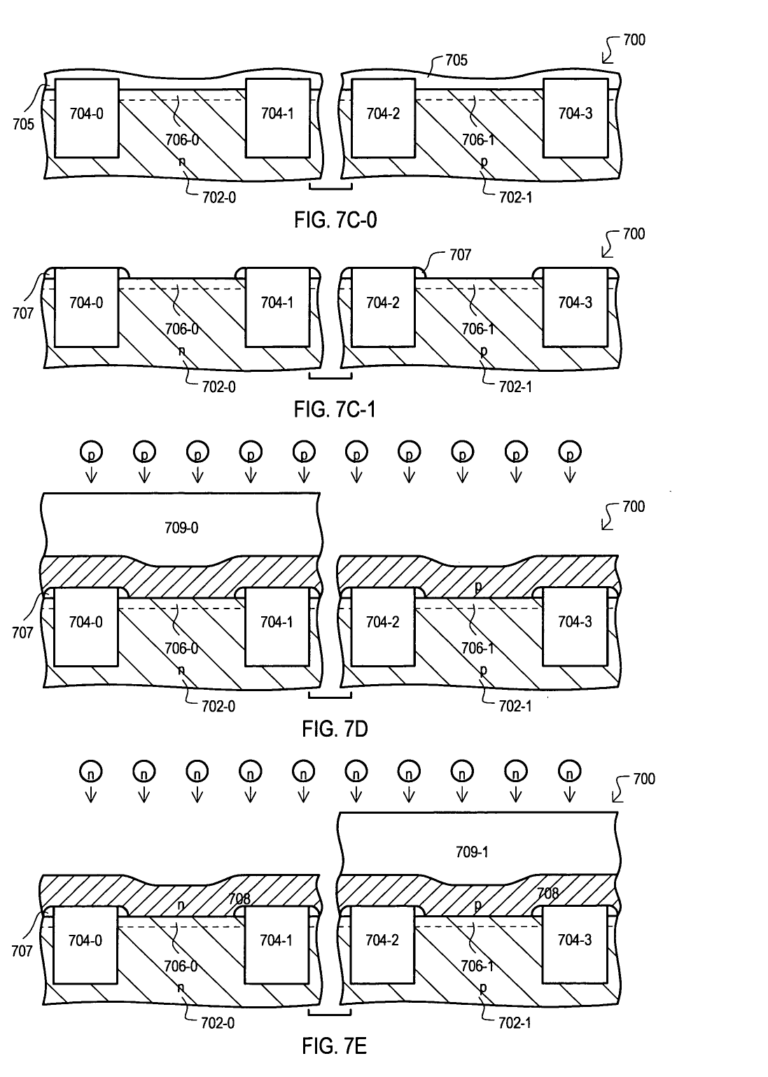

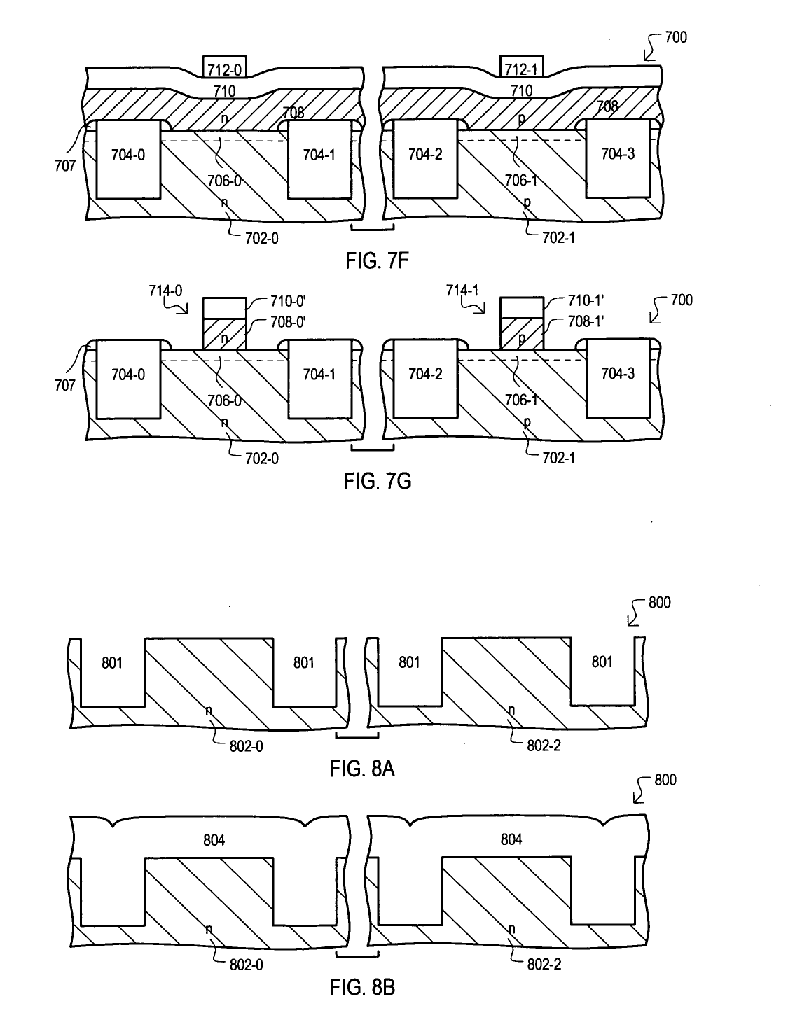

Another example of a method for forming complementary JFETs in a same integrated circuit is shown in FIGS. 7A to 7G, which show side cross sectional views of a semiconductor device 700 following various processing steps.

Method steps shown by FIGS. 7A to 7C can be the same as those of FIGS. 6A to 6C, thus like structures are referred to by the same reference character but with the first digit being a “7” instead of a “6”. A description of FIGS. 7A to 7C will be omitted to avoid repetition.

Referring now to FIG. 7C-0, unlike the method of FIGS. 6A to 6H, the formation of semiconductor device 700 can include depositing an insulating fill layer 705 over first and second substrate portions (702-0 and 702-1). Preferably, a fill insulating layer 705 can be a layer of deposited silicon nitride.

Referring now to FIG. 7C-1, a method can further include anisotropically etching fill insulating layer 705 to form fill spacers (one shown as 707) at corners formed by isolation structures (704-0 to 704-3) and a surface of substrate portions (702-0 to 702-1).

FIG. 7D can show the same general steps as FIG. 6D. However, it is noted that an electrode layer 708 does not occupy corners formed by isolation structures (704-0 to 704-3) and a surface of substrate portions (702-0 to 702-1), as such areas are occupied by fill spacers (e.g., 707).

FIGS. 7E to 7G can show the same general method steps as FIGS. 6E to 6G. However, as shown by FIG. 7G, following an electrode patterning step, corners formed by isolation structures (704-0 to 704-3) and a surface of substrate portions (702-0 to 702-1) can remain free of residual electrode material due to fill spacers (e.g., 707).

In this way, complementary type JFETs can be formed in the same substrate essentially without residual electrode material by forming a fill spacer at locations susceptible to retaining electrode material.

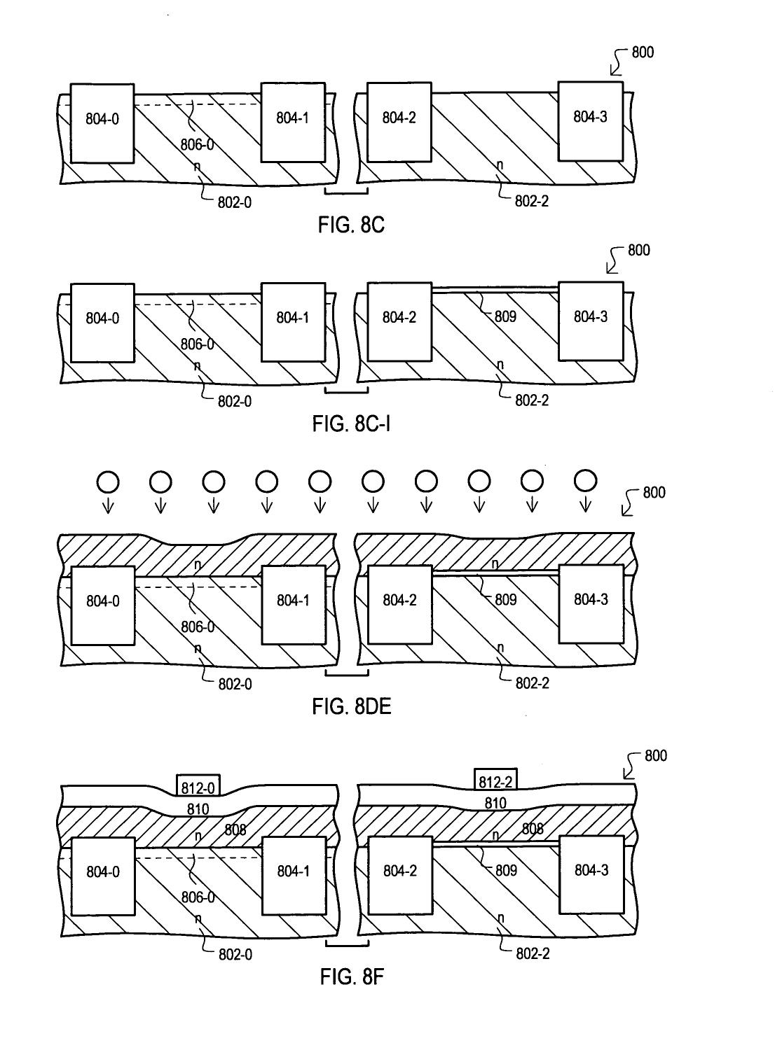

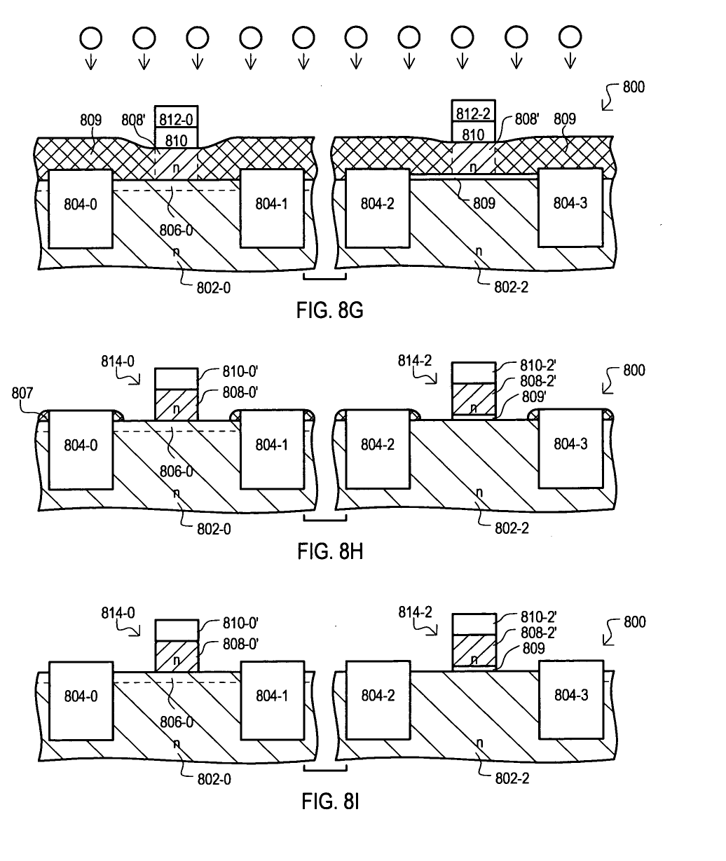

The above embodiments of FIGS. 6A to 6H and 7A to 7H have shown methods that can form complementary JFET structures. In other embodiments, such JFET structures can be integrated with insulated field effect transistor (IGFET) structures in a same substrate. One example of such an arrangement is shown in FIGS. 8A to 8I, which show side cross sectional views of a semiconductor device 800 during and following various processing steps.

Method steps shown by FIGS. 8A and 8B can be the same as those of FIGS. 6A and 6B, thus like structures are referred to by the same reference character but with the first digit being an “8” instead of a “6”. Further, a description of such figures will be omitted.

Referring now to FIG. 8C, unlike the above embodiments, following a planarization step, while a JFET channel (e.g., 806-0) can be formed in a first substrate portion 802-0, an insulated gate portion 802-2 will not include such a channel region. For example, insulated gate portion 802-2 can be covered by an implant mask during such JFET channel formation steps. Still further, if an inherent conductivity of substrate (including an n-type well) is not sufficient for a desired IGFET performance, such a region can be subject to a transistor threshold voltage adjustment ion implantation, while JFET regions are masked.

FIG. 8C shows insulated gate portion 802-2 as an n-type substrate that can form a p-channel IGFET. However, such a region could be p-type to accommodate the formation of an n-channel IGFET.

Referring now to FIG. 8C-I, a method can include forming a gate insulating layer over an active area of insulated gate portion 802-2. Such a step can include a conventional gate oxidation step, or alternatively the deposition of gate insulator, or some combination thereof. A gate insulating layer 802-0 is not formed over first portion 802-0. Such a region can be masked from a gate insulating layer formation step, or such a region can be subject to an etch step that removes a gate insulating layer while an insulated gate portion 802-2 is masked.

Referring to FIG. 8DE, a method can include a step similar to that shown in FIG. 6D or 6E that dopes an electrode layer 808 to a desired conductivity type and level. It is understood that while FIG. 8DE shows a same ion implantation step for the electrode layer 808 over both a first portion 802-0 and an insulated gate portion 802-2, separate ion implantation steps can be performed for these portions.

Referring to FIG. 8F, a method can include the same steps as shown in FIG. 6F. However, it is understood that etch mask 812-2 corresponds to the location of an IGFET gate.

Referring to FIG. 8G, a method can include the same general steps as FIG. 6G.

Referring to FIG. 8H, a method can include an electrode patterning step that can include the same general steps as shown in FIG. 6H. However, such a patterning step can include an additional etch step, or variation in etch recipe, for removing gate insulator 809 to expose the IGFET active area. Following an electrode patterning step, an IGFET gate structure 814-2 can be formed that includes a gate insulator portion 809′, a gate electrode portion 808-2′, and gate protection portion 810-2′. As shown by FIG. 8H, following the formation of JFET and IGFET gate structures, residual electrode material (e.g., 807) can remain at corners formed by isolation structures (804-0 to 804-3) and a surface of substrate portions (802-0 and 802-2).

Referring to FIG. 8I, a method can include the same general steps as shown in FIG. 6I, resulting in the removal of residual electrode material.

In this way, JFETs can be formed in the same substrate as IGFETs essentially without residual electrode material. Of course, IGFETs like that shown in FIGS. 8A to 8I can be formed with complementary JFETs as shown in FIGS. 6A to 6I.

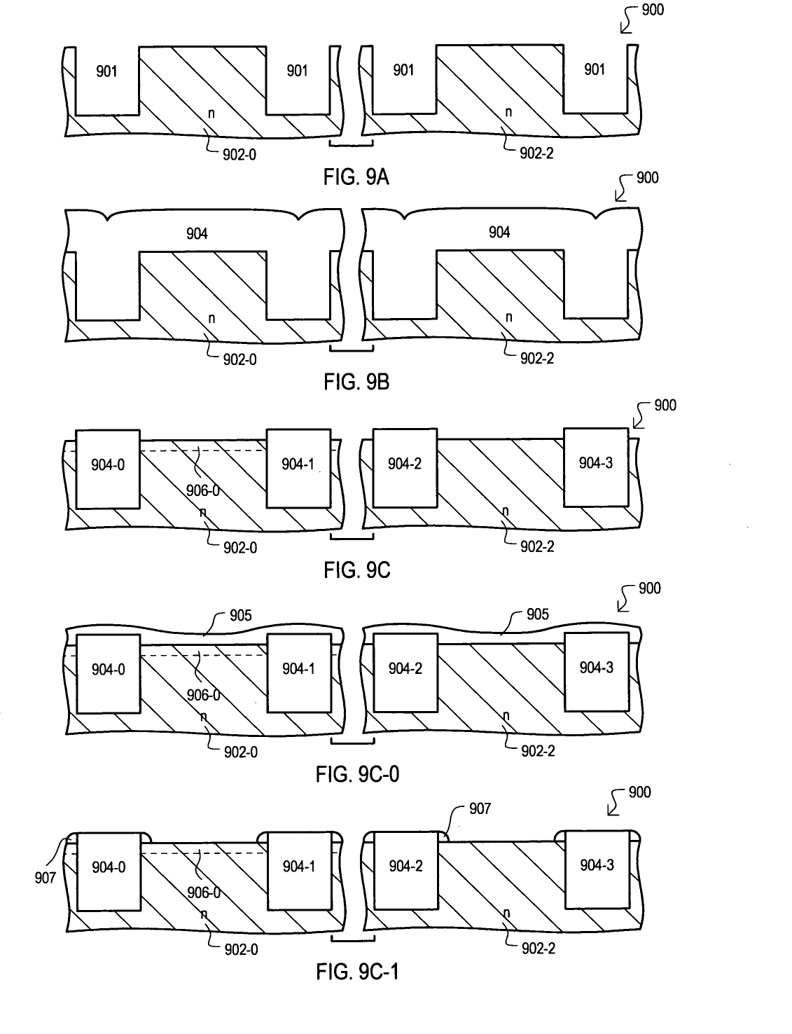

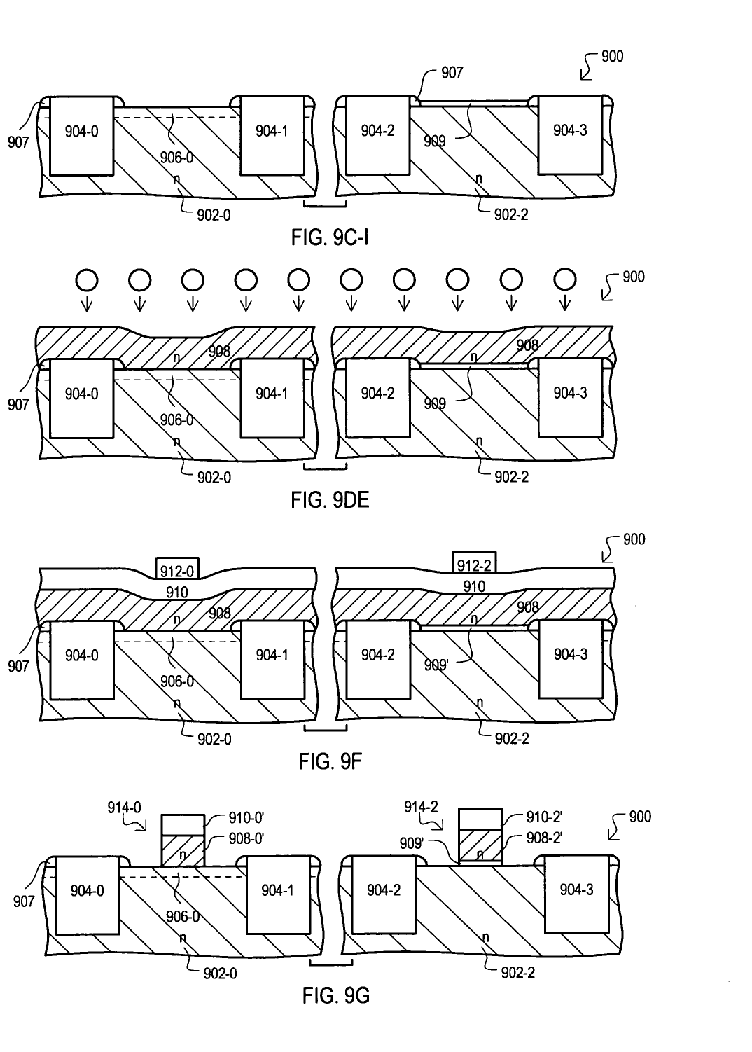

Another example of a method for forming JFET and IGFETs in a same integrated circuit is shown in FIGS. 9A to 9G, which show side cross sectional views of a semiconductor device 900 following various processing steps.

Method steps shown by FIGS. 9A to 9C-1 can be the same as those of FIGS. 7A to 7C-1, thus like structures are referred to by the same reference character but with the first digit being a “9” instead of a “7”. However, unlike the embodiment of FIGS. 7A to 7C-1, a substrate can include an insulated gate portion 902-2 for containing an IGFET. Within insulated gate portion 902-2 can be fill spacers (one shown as 907) at corners formed by isolation structures (9040 to 9043) and a surface of insulated gate portion 902-2.

Referring now to FIG. 9C-I, a method can include the same general steps as shown in FIG. 8C-I. A gate insulator 909 can be formed over an insulated gate portion 902-2 of a substrate.

FIG. 9DE shows the same general method steps as described in conjunction with FIG. 8DE. Doping for gate electrodes of a JFET and IGFET can be implemented with a same ion implantation, different ion implantations, or a combination of both.

FIGS. 9F and 9G show the same general steps as FIGS. 7F and 7G. An anisotropic etch can form a JFET gate structure 9140 and an IGFET gate structure 914-2. Further, residual electrode material can be prevented from forming by fill spacers (one shown as 907) occupying corners formed by isolation structures (904-0 to 904-3) and a surface of insulated gate portion 902-2. As in the case of FIG. 8G, additional etch steps, or variation in recipe may be needed to remove gate insulator 909 and expose active areas below.

In this way, both JFETs and IGFETs can be formed in the same substrate essentially without residual electrode material by forming a fill spacer at locations susceptible to retaining electrode material. As in the case of FIGS. 8A to 8H, the method shown in FIGS. 9A to 9G can form complementary JFETs as shown in FIGS. 6A to 6H.

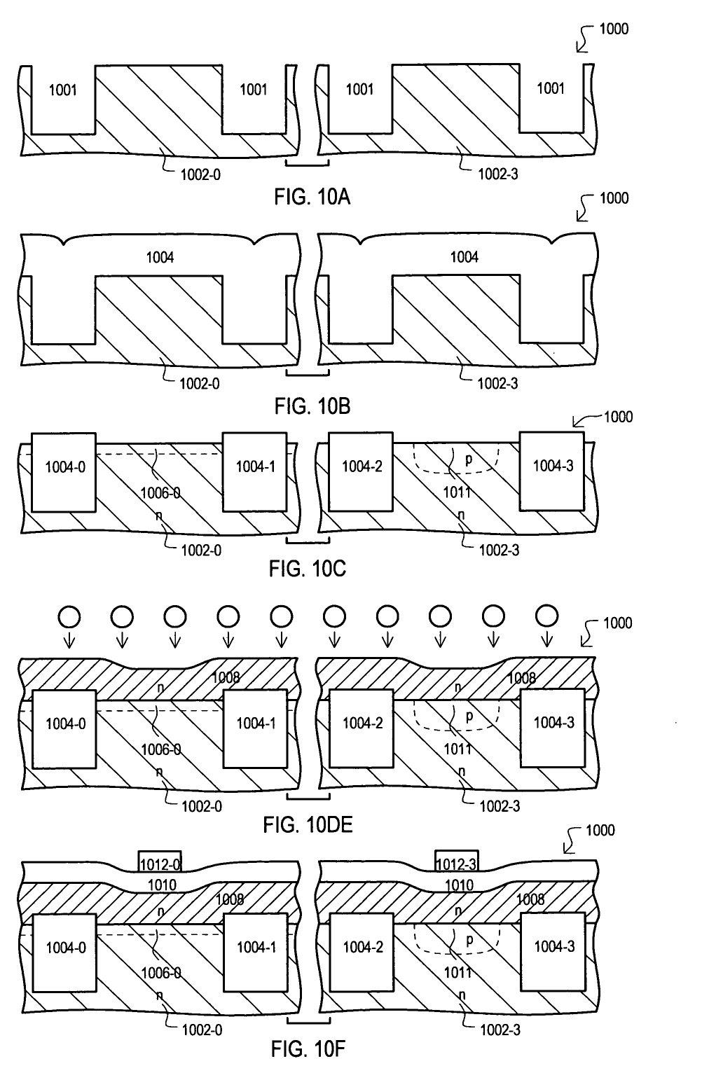

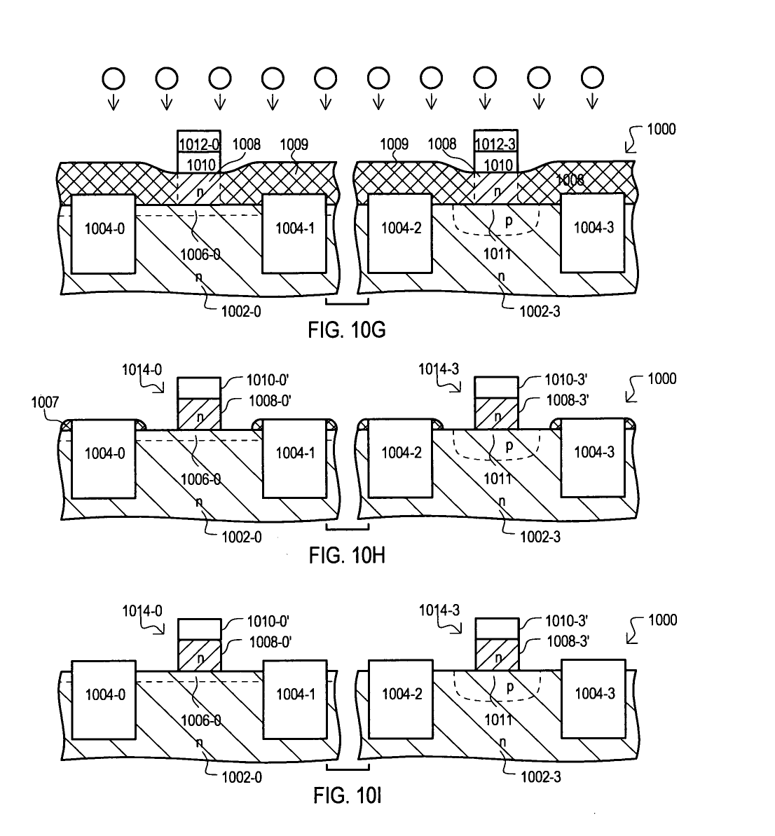

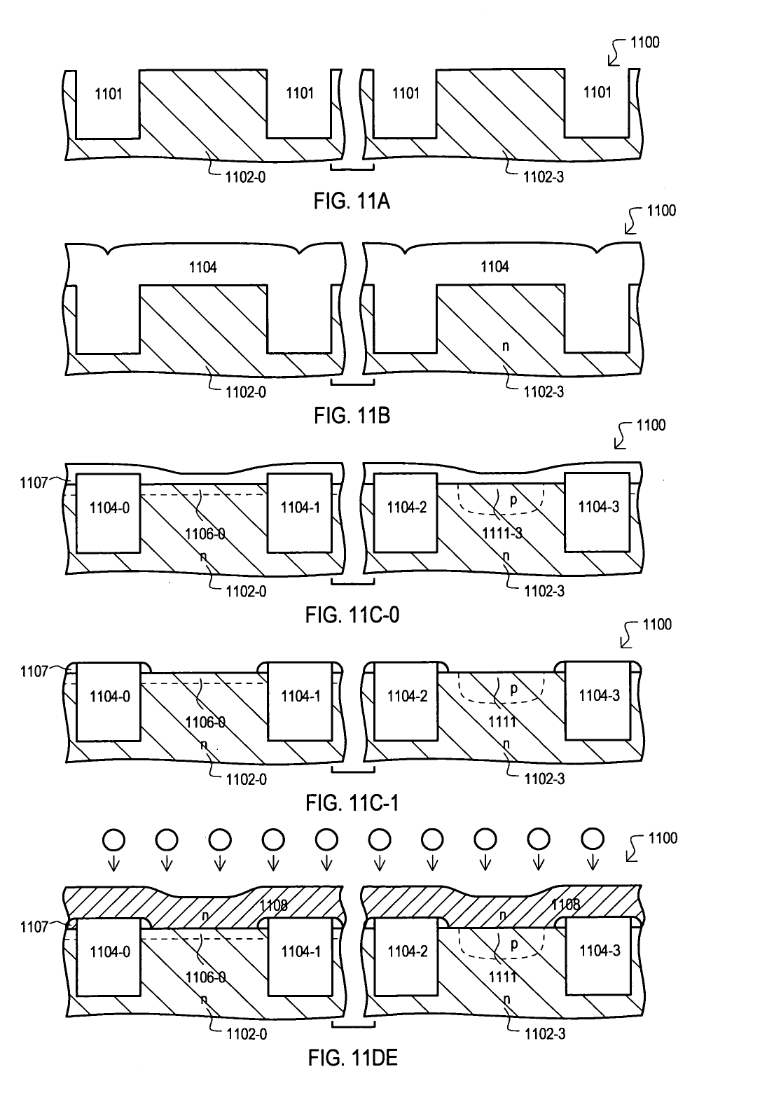

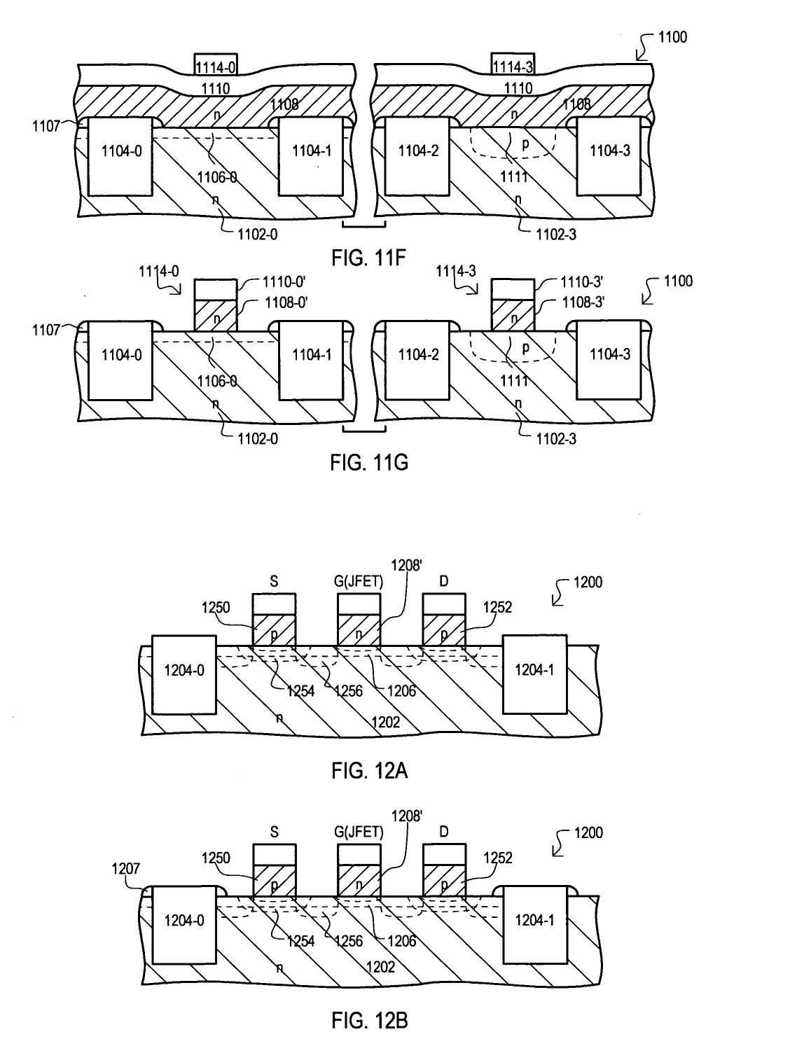

In still other embodiments, JFET structures can be integrated with bipolar junction transistor (BJT) structures in a same substrate. Two examples of such an arrangement are shown in FIGS. 10A to 10I and 11A to 11G.

The example of FIGS. 10A to 10I generally follows that of FIGS. 8A to 8I. However, as shown in FIG. 10C, a base region 1011 can be formed within a bipolar portion 1002-3 of a substrate, by an ion implantation step, for example. In addition, a patterning step of FIG. 10H can form an emitter electrode structure 1014-3.

Similarly, the example of FIGS. 11A to 11G generally follows that of FIGS. 9A to 9G. However, as shown in FIG. 11C1, a base region 1011 can be formed within a bipolar portion 1102-3, and a patterning step shown by FIG. 11G can form emitter structure 1114-3.

In this way, both JFETs and BJTs can be formed in the same substrate essentially without residual electrode material. This method can also form complementary JFETs as shown in FIGS. 6A to 6I.

It is understood that an electrode layer patterned to form a JFET gate electrode, IGFET gate electrode, or BJT emitter can also form electrodes for other terminals of such devices. Examples of such structures are shown in FIGS. 12A to 14B.

FIGS. 12A and 12B show the formation of source, drain and gate electrodes of a p-channel JFET from a common electrode layer. FIG. 12A shows a resulting structure when residual electrode material is etched away. FIG. 12B shows a resulting structure with fill spacers (e.g., 1207) that prevent an electrode layer from occupying hard to fill areas. Source and drain electrodes (1250 and 1252) can be doped to a conductivity type the same as a channel region 1206, while gate electrode 1208′ can be doped to a conductivity type opposite to the channel region 1206.

In the particular example of FIGS. 12A and 12B, source/drain regions can include a first region 1254 formed by a doping step performed prior to the formation of an electrode layer, or formed by out-diffusion of dopants from the respective source/drain electrode (1250/1252), or some combination thereof. A second region 1256 can be formed by doping steps performed after the electrodes (1308′, 1350 and 1352) have been formed, such as an ion implantation step.

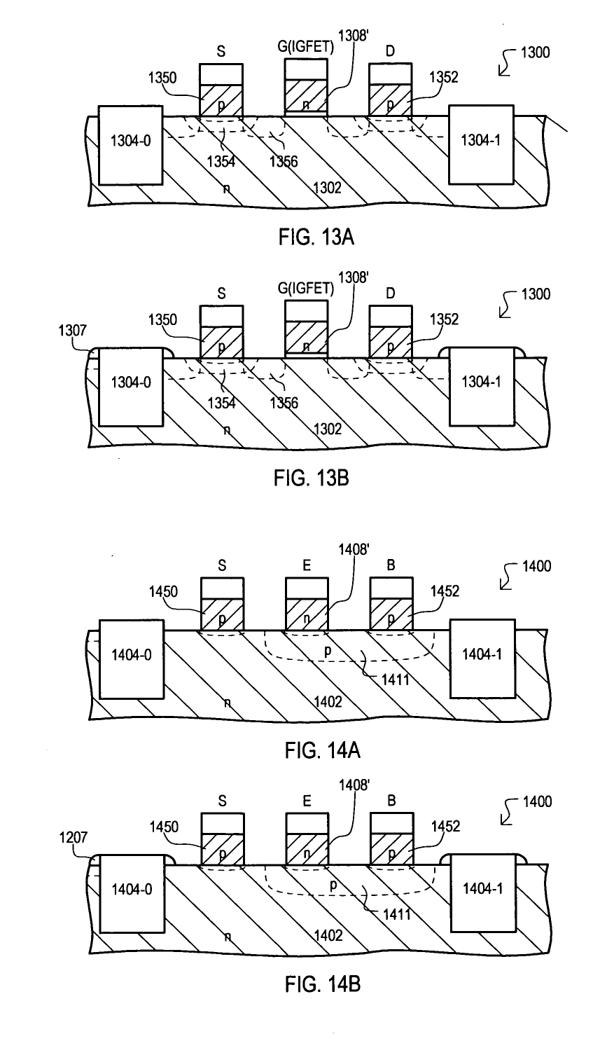

FIGS. 13A and 13B show the formation of source, drain and gate electrodes of an IGFET from a common electrode layer. FIG. 13A shows a resulting structure when residual electrode material is etched away, while FIG. 13B shows an approach using fill spacers (e.g., 1307). Source and drain electrodes (1350 and 1352) can be doped to a conductivity type the same as source/drain regions formed in a substrate below. In the particular example of FIGS. 13A and 13B, source/drain regions can be formed in the same fashion as FIGS. 12A and 12B.

FIGS. 14A and 14B show the formation of emitter, base and collector electrodes of a BJT from a common electrode layer. FIG. 14A shows a resulting structure when residual electrode material is etched away, while FIG. 14B shows an approach using fill spacers (e.g., 1407). A collector electrode 1458 and emitter electrode 1460 can be doped to a conductivity type opposite that of a base region 1411. A base electrode 1462 can be doped to a same conductivity type as base region 1411.

It is understood that materials selected can vary according to process technology. Further, references to oxides and nitrides should be construed as being limited to stoichiometric forms of such materials. That is, a silicon oxide should not be construed as being limited to silicon dioxide. Similarly, polysilicon can include other forms such as amorphous silicon.

Still further, substrate structures can vary according to manufacturing process used. As but a few examples, a resulting difference in an isolation structure height and substrate surface could arise in silicon-on-insulator structures. Accordingly, a substrate should not necessarily be construed as limited to a monocrystalline substrate. Further, for embodiments that integrate JFETs with bipolar transistors, a substrate can include epitaxial grown silicon with a buried layer that can form a portion of a BJT device.

In the above description, for purposes of explanation, numerous specific details are set forth in order to provide a thorough understanding of the present invention. It will be evident, however, to one skilled in the art that the present invention may be practices without these specific details. In other instances, well-known circuits, structures, and techniques may not be shown in detail to avoid unnecessarily obscuring an understanding of this description.

Reference in the description to “one embodiment” or “an embodiment” means that a particular feature, structure, or characteristic described in connection with the embodiment is included in at least one embodiment of the invention. The appearance of the phrase “in one embodiment” in various places in the specification do not necessarily all refer to the same embodiment. The term “to couple” or “electrically connect” as used herein may include both to directly and to indirectly connect through one or more intervening components.

Further it is understood that the embodiments of the invention may be practiced in the absence of an element or step not specifically disclosed. That is an inventive feature of the invention may include an elimination of an element.

While various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A method of forming a semiconductor device, comprising:
forming a first layer of semiconductor material in contact with a first area of a substrate, the first area being adjacent to at least one electrical isolation structure that extends into the substrate and has a top portion extending above a surface of the substrate;
etching, with a degree of anisotropy, the first layer to form at least a first structure in contact with the first area; and
in a step separate from the etching step, preventing retention of residual semiconductor material at a junction of the substrate and the at least one electrical isolation structure.

2. The method of claim 1, wherein
preventing retention of the semiconductor material includes,
prior to etching with a degree of anisotropy,
selectively doping the semiconductor material to form electrode portions and removal portions;
after etching with a degree of anisotropy,
etching, to remove residual semiconductor material at the junction of the substrate and the at least one electrical isolation structure with an etch selective to the removal portions over the electrode portions.

3. The method of claim 2, wherein:
etching to remove the residual semiconductor material includes a wet chemical etch.

4. The method of claim 3, wherein:
the wet chemical etch comprises hydrofluoric acid.

5. The method of claim 3, wherein:
the wet chemical etch comprises nitric acid.

6. The method of claim 2, wherein:
etching to remove the residual semiconductor material includes a plasma etch.

7. The method of claim 6, wherein:
the plasma etch includes disassociated chlorine.

8. The method of claim 1, wherein:
preventing retention of the semiconductor material includes, prior to etching with a degree of anisotropy,
forming an insulating structure that fills the junction of the substrate and the at least one electrical isolation structure, but does not substantially extend above the at least one electrical isolation structure.

9. The method of claim 8, wherein:
forming the insulating structure includes
depositing a fill insulating film over at least the junction of the substrate and the electrical isolation structure, and
etching the fill insulating film, with a degree of anisotropy, to form a sidewall structure at the junction of the substrate and the electrical isolating structure.

10. The method of claim 9, wherein:
the fill insulating film comprises silicon nitride.

11. The method of claim 1, wherein:
the substrate comprises silicon.

12. The method of claim 11, wherein:
the substrate further comprises germanium.

13. The method of claim 11, wherein:
the substrate further comprises carbon.

14. The method of claim 1, wherein:
the semiconductor material comprises polysilicon.

15. The method of claim 1, wherein:
the substrate comprises a semiconductor doped to a first conductivity type and the semiconductor material is doped to a second conductivity type.

16. The method of claim 1, wherein:
the first structure comprises a gate electrode a junction field effect transistor (JFET).

17. The method of claim 1, wherein:
the first structure is selected from group consisting of a source electrode and drain electrode of a junction field effect transistor (JFET).

18. The method of claim 1, wherein:
the substrate is a semiconductor doped to a first conductivity type; and
etching with a degree of anisotropy to form at least a first structure in contact with the substrate includes
forming a source contact and a drain contact doped to the first conductivity type, and
forming a gate doped to a second conductivity type.

19. The method of claim 1, wherein:
forming the first layer of semiconductor material in contact with a first area of a substrate, includes forming the semiconductor material in contact with a second area of the substrate, the first area comprising a semiconductor doped to a first conductivity type, the second first area comprising a semiconductor doped to a second conductivity type;
the second area being adjacent to a second electrical isolation structure that extends into the substrate and has a top portion extending above a surface of the substrate;
the first structure comprises a first junction field effect transistor (JFET) gate doped to the second conductivity type
etching with a degree of anisotropy also includes forming a second a JFET gate doped to the first conductivity type in contact with the second area; and
preventing retention of residual semiconductor material further includes preventing retention of residual semiconductor material at a junction of the substrate and the second electrical isolation structure.

20. The method of claim 1, wherein:
etching with a degree of anisotropy removes the first layer without substantially etching the substrate.

21. The method of claim 1, further including:
after forming the first layer, doping different sections of the first layer to different conductivity types.

22. The method of claim 1, further including:
forming a first layer of semiconductor material further includes forming the first layer in contact with a gate insulator formed on a insulated gate area of the substrate, the insulated gate area being adjacent to an insulated gate electrical isolation structure that extends into the substrate and has a top portion extending above a surface of the substrate;
etching with a degree of anisotropy further forms an insulated gate structure formed over the gate insulator; and
preventing retention of residual semiconductor material at a junction of the substrate and insulated gate electrical isolation structure.

23. The method of claim 1, wherein:
forming a first layer of semiconductor material further includes forming the first layer in contact with a second area of the substrate, the second area being adjacent to a bipolar electrical isolation structure that extends into the substrate and has a top portion extending above a surface of the substrate;
etching with a degree of anisotropy further forms a bipolar transistor emitter structure in contact with the second area; and
preventing retention of residual semiconductor material at a junction of the substrate and the bipolar electrical isolation structure.

24. A semiconductor device, comprising:
at least a first isolation structure that extends into a semiconductor substrate and includes a top portion that extends above a surface of the semiconductor substrate;
at least a first semiconductor electrode formed on, and in contact with the semiconductor substrate; and
a fill spacer that fills a corner formed by the substrate and the top portion of the first isolation structure, the fill spacer comprising an insulating material.

25. The semiconductor device of claim 24, wherein:
the at least first isolation structure comprises silicon dioxide formed in and above an etched trench to create a shallow trench isolation structure.

26. The semiconductor device of claim 24, wherein:
the first semiconductor electrode comprises a junction field effect transistor gate electrode doped to a first conductivity type and formed over a portion of the semiconductor substrate that is doped to a second conductivity type.

27. The semiconductor device of claim 24, further including:
a second semiconductor electrode formed on, and in contact with the semiconductor substrate, the second semiconductor electrode comprises a junction field effect transistor source/drain electrode doped to the second conductivity type and formed over a portion of the semiconductor substrate that is doped to the second conductivity type.

28. The semiconductor device of claim 24, further including:
a second isolation structure that extends into a semiconductor substrate and includes a top portion that extends above a surface of the semiconductor substrate;
the first semiconductor electrode is of a first conductivity type and is formed on, and in contact with a first area of the semiconductor substrate of a second conductivity type;
a second semiconductor electrode of the second conductivity type formed on, and in contact with a second area of the semiconductor substrate of the first conductivity type; and
a second fill spacer that fills a corner formed by the substrate and the top portion of the second isolation structure, the fill spacer comprising the insulating material.

29. The semiconductor device of claim 24, further including:
the at least a first isolation structure further includes an insulated gate device isolation structure that extends into a semiconductor substrate and includes a top portion that extends above a surface of the semiconductor substrate adjacent to an insulated gate area of the substrate;
a gate insulator formed over the insulated gate area;
an insulated gate electrode formed on, and in contact with the insulated gate area; and
an insulated gate device fill spacer that fills a corner formed by the substrate and the insulated gate area, the fill spacer comprising an insulating material.

30. The semiconductor device of claim 24, wherein:
the at least a first isolation structure further includes a bipolar device isolation structure that extends into a semiconductor substrate and includes a top portion that extends above a surface of the semiconductor substrate adjacent to a bipolar area of the substrate; and
a bipolar emitter electrode formed on, and in contact with the bipolar area.

31. A semiconductor device, comprising:
at least a first isolation structure that extends into a semiconductor substrate and includes a top portion that extends above a surface of the semiconductor substrate;
at least a first semiconductor electrode formed on, and in contact with the semiconductor substrate formed from a semiconductor material; and
a junction between the first isolation structure and the semiconductor substrate substantially free of the semiconductor material by an etch step different from a patterning step that forms the first semiconductor electrode.

32. The semiconductor device of claim 31, wherein:
the at least first isolation structure comprises silicon dioxide formed in and above an etched trench to create a shallow trench isolation structure.

33. The semiconductor device of claim 31, wherein:
the first semiconductor electrode comprises a junction field effect transistor gate electrode doped to a first conductivity type and formed over a portion of the semiconductor substrate that is doped to a second conductivity type.

34. The semiconductor device of claim 31, further including:
a second semiconductor electrode formed on, and in contact with the semiconductor substrate, the second semiconductor electrode comprises a junction field effect transistor source/drain electrode doped to the second conductivity type and formed over a portion of the semiconductor substrate that is doped to a second conductivity type.

35. The semiconductor device of claim 31, further including:
a second isolation structure that extends into a semiconductor substrate and includes a top portion that extends above a surface of the semiconductor substrate;
the first semiconductor electrode is of a first conductivity type and is formed on, and in contact with a first area of the semiconductor substrate of a second conductivity type;
a second semiconductor electrode of the second conductivity type formed on, and in contact with a second area of the semiconductor substrate of the first conductivity type; and
a junction between the first isolation structure and the semiconductor substrate substantially free of the semiconductor material by the etch step different from the patterning step that forms the first semiconductor electrode.

36. The semiconductor device of claim 31, further including:
the at least a first isolation structure further includes an insulated gate device isolation structure that extends into a semiconductor substrate and includes a top portion that extends above a surface of the semiconductor substrate adjacent to an insulated gate area of the substrate;
a gate insulator formed over the insulated gate area;
an insulated gate electrode formed on, and in contact with the insulated gate area; and
a junction between the insulated gate device isolation structure and the semiconductor substrate substantially free of the semiconductor material by the etch step different from the patterning step that forms the insulated gate electrode.

37. The semiconductor device of claim 31, wherein:
the at least a first isolation structure further includes a bipolar device isolation structure that extends into a semiconductor substrate and includes a top portion that extends above a surface of the semiconductor substrate adjacent to a bipolar area of the substrate; and
a bipolar emitter electrode formed on, and in contact with the bipolar area.
